(19) United States
(12) Patent Application Publication
(10) Pub. No.: US 2018/0130791 A1
(43) Pub. Date: May 10, 2018

(54) ELECTRONIC CIRCUIT, INTEGRATED CIRCUIT AND MOTOR ASSEMBLY

(71) Applicant: Johnson Electric S.A., Murten (CH)

(72) Inventors: Chiping SUN, Hong Kong (CN); Ken WONG, Hong Kong (CN); Shujuan HUANG, Shenzhen (CN); Yunlong JIANG, Shenzhen (CN); Shinghin YEUNG, Hong Kong (CN)

(21) Appl. No.: 15/804,089

(22) Filed: Nov. 6, 2017

(30) Foreign Application Priority Data
Nov. 4, 2016 (CN) 2016 1097 8243.1

(51) Int. Cl. H01L 27/02; H02H 9/04

(52) U.S. Cl. CPC H01L 27/0266; H02H 9/046

(57) ABSTRACT

An electronic circuit includes an output port, a first AC input port and a second AC input port connecting with an external AC power source, a rectifier circuit. The rectifier circuit includes a first input terminal coupled with the first AC input port, a second input terminal coupled with the second AC input port, a first output terminal and a second output terminal. A voltage of the first output terminal is larger than a voltage of the second output terminal. The electronic circuit further includes a first bidirectional electrostatic protection circuit coupled between the first AC input port and the second output terminal of the rectifier circuit; a second bidirectional electrostatic protection circuit coupled between the second AC input port and the second output terminal of the rectifier circuit; and a third bidirectional electrostatic protection circuit coupled between the output port and the second output terminal of the rectifier circuit.

### CROSS REFERENCE TO RELATED APPLICATIONS

This non-provisional patent application claims priority under 35 U.S.C. § 119(a) from Patent Application No. 201610978243.1 filed in the People's Republic of China on Nov. 4, 2016.

### TECHNICAL FIELD

The present disclosure relates to electrostatic protection field, in particular to an electrostatic protecting circuit, an integrated circuit and a motor assembly using the integrated circuit.

### BACKGROUND

ESD (Electro-Static Discharge) can damage electronic components or make an electrical over stress (ESO) of an integrated circuit. Moreover, due to a very high ESD voltage, the electronic components or integrated circuit can be damaged permanently; the electronic components and integrated circuit can't normally work. Therefore, the prevention of electrostatic damage has become an important research direction for the design and manufacture of electronic components and integrated circuit.

### SUMMARY

An electronic circuit includes an output port, a first AC input port and a second AC input port connecting with an external AC power source, a rectifier circuit. The rectifier circuit includes a first input terminal coupled with the first AC input port, a second input terminal coupled with the second AC input port, a first output terminal and a second output terminal. A voltage of the first output terminal is larger than a voltage of the second output terminal. The electronic circuit further includes a first bidirectional electrostatic protection circuit coupled between the first AC input port and the second output terminal of the rectifier circuit; a second bidirectional electrostatic protection circuit coupled between the second AC input port and the second output terminal of the rectifier circuit; and a third bidirectional electrostatic protection circuit coupled between the output port and the second output terminal of the rectifier circuit.

Preferably, the second output terminal is a floating ground end.

Preferably, the electronic circuit further includes a Zener diode and a current limiting resistor coupled between the first output terminal of the rectifier circuit and the second output terminal of the rectifier circuit in series.

Preferably, the electronic circuit further includes a fourth bidirectional electrostatic protection circuit coupled between the first output terminal and the second output terminal of the rectifier circuit.

Preferably, the electronic circuit further includes a fifth bidirectional electrostatic protection circuit coupled between the first AC input port and the second AC input port.

Preferably, at least one of the first, second, third, fourth and fifth bidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

Preferably, at least one of the first, second, third, fourth and fifth bidirectional electrostatic protection circuit comprises an electrostatic detection circuit and a semiconductor element, and when an static electricity is not generated in the electronic circuit, the semiconductor element is in a high resistance state; and when the static electricity is generated in the electronic circuit, the semiconductor element is controlled to be conductive by the electrostatic detection circuit to form a discharge path to release the static electricity.

Preferably, at least one of the first, second, third, fourth and fifth bidirectional electrostatic protection circuit comprises a bidirectional trigger diode.

Preferably, at least one of the first, second, third, fourth and fifth bidirectional electrostatic protection circuit comprises a first Zener diode and a second Zener diode; a cathode of the first Zener diode is coupled with a cathode of the second Zener diode, an anode of the first Zener diode and an anode of the second Zener diode are two ports of the bidirectional electrostatic protection circuit.

Preferably, at least one of the first, second, third, fourth and fifth bidirectional electrostatic protection circuit comprises a first Zener diode and a second Zener diode; an anode of the first Zener diode is coupled with an anode of the second Zener diode, a cathode of the first Zener diode and a cathode of the second Zener diode are two ports of the bidirectional electrostatic protection circuit.

Preferably, at least one of the first, second, third, fourth and fifth bidirectional electrostatic protection circuit comprises two sub-protection circuits which are connected in reverse parallel, each of the two sub-protection circuits comprises a PNP transistor, an NPN transistor, a second resistor and a plurality of diodes. A base electrode of the PNP transistor is electrically coupled with a collector electrode of the NPN transistor. A collector electrode of the PNP transistor is electrically coupled with a base electrode of the NPN transistor and coupled to an emitter electrode of the NPN transistor via the second resistor. The plurality of diodes are coupled between the collector electrode NPN transistor and the emitter electrode of the NPN transistor; and an emitter electrode of the PNP transistor is electrically coupled to the emitter electrode of the NPN transistor of the other sub-protection circuit, the emitter electrodes of the NPN transistor in two sub-protection circuits are two ports of the bidirectional electrostatic protection circuit.

Preferably, at least one of the first, second, third, fourth and fifth bidirectional electrostatic protection circuit comprises a first diode, a second diode, a third diode, a fourth diode, a third resistor, a first capacitor, a PMOS transistor, a first NMOS transistor, a fourth resistor, and a second NMOS transistor. An anode of the first diode is electrically coupled with a cathode of the second diode, a cathode of the first diode is electrically coupled with a cathode of the third diode, a cathode of the second diode and an anode of the third diode are two ports of the bidirectional electrostatic protection circuit. A cathode of the fourth diode is electrically coupled with an anode of the third diode, an anode of the fourth diode is electrically coupled with an anode of the second diode. One end of the third resistor is electrically coupled with the cathode of the first diode, the other end of the third resistor is electrically coupled with one end of the first capacitor, the other end of the first capacitor is electrically coupled with the anode of the second diode. A drain of the PMOS is electrically coupled with the cathode of the first diode, a gate of the PMOS is electrically coupled with the other end of the third resistor and a gate of the first NMOS transistor, a source of the PMOS is electrically coupled with a drain of the first NMOS transistor and a gate of the second NMOS, a source of the first NMOS is electrically coupled with the anode of the second diode; and a drain of the second NMOS transistor is electrically coupled with the cathode of the first diode via the fourth resistor, a source of the NMOS transistor is electrically coupled with the anode of the second diode.

An integrated circuit includes a housing, a semiconductor substrate arranged in the housing, an electronic circuit arranged on the semiconductor. The integrated circuit includes a first input port, a second input port, and an output port which extending from the housing. The integrated circuit further includes a floating ground end; a first bidirectional electrostatic protection circuit coupled between the first input port and the floating ground end; a second bidirectional electrostatic protection circuit coupled between the second input port and the floating ground end; and a third bidirectional electrostatic protection circuit coupled between the output port and the floating ground end.

Preferably, the electronic circuit further comprises a rectifier circuit having a first input terminal coupled to the first input port, a second input terminal coupled to a second input port, a first output terminal and a second output terminal.

Preferably, the electronic circuit further comprises a fourth bidirectional electrostatic protection circuit coupled between the first output terminal and the second output terminal of the rectifier circuit.

Preferably, the electronic circuit further comprises a fifth bidirectional electrostatic protection circuit coupled between the first input port and the second input port.

Preferably, at least one of the first, second, third, fourth and fifth bidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

Preferably, at least one of the first, second, third, fourth and fifth bidirectional electrostatic protection circuit comprises an electrostatic detection circuit and a semiconductor element, and when an static electricity is not generated in the electronic circuit, the semiconductor element is in a high resistance state; and when the static electricity is generated in the electronic circuit, the semiconductor element is controlled to be conductive by the electrostatic detection circuit to form a discharge path to release the static electricity.

A motor assembly includes a motor and a motor-driven circuit, and the motor-driven circuit comprises the integrated circuit as described-above.

### BRIEF DESCRIPTION OF THE DRAWINGS

FIG. 1 shows a block diagram of an electronic circuit having an electrostatic protection circuit according to one embodiment.

FIG. 2 shows a block diagram of an electronic circuit having an electrostatic protection circuit according to another embodiment.

FIG. 3 shows a block diagram of an electronic circuit having an electrostatic protection circuit according to another embodiment.

FIG. 4 shows a block diagram of an electronic circuit having an electrostatic protection circuit according to another embodiment.

FIG. 5 shows a block diagram of an electronic circuit having an electrostatic protection circuit according to another embodiment.

FIGS. 6a -6e show a circuit diagram of an electrostatic protection circuit of an electronic circuit.

FIG. 7 shows a block diagram of an integrated circuit according to one embodiment.

FIG. 8 shows a block diagram of an integrated circuit according to another embodiment.

FIG. 9 shows a block diagram of an integrated circuit according to another embodiment.

FIG. 10 shows a schematic diagram of a motor assembly according to one embodiment.

The following implementations are used for the description of the present disclosure in conjunction with above figures.

### DETAILED DESCRIPTION OF THE EMBODIMENTS

Hereinafter technical solutions in embodiments of the present disclosure are described clearly and completely in conjunction with the drawings in embodiments of the present disclosure. Apparently, the described embodiments are only some rather than all of the embodiments of the present disclosure. Any other embodiments obtained based on the embodiments of the present disclosure by those skilled in the art without any creative work fall within the scope of protection of the present disclosure. It is understood that, the drawings are only intended to provide reference and illustration, and not to limit the present disclosure. The connections in the drawings are only intended for the clearance of description, and not to limit the type of connections.

It should be noted that, if a component is described to be “connected” to another component, it may be connected to another component directly, or there may be an intervening component simultaneously. All the technical and scientific terms in the present disclosure have the same definitions as the general understanding of those skilled in the art, unless otherwise defined. Herein the terms in the present disclosure are only intended to describe embodiments, and not to limit the present disclosure.

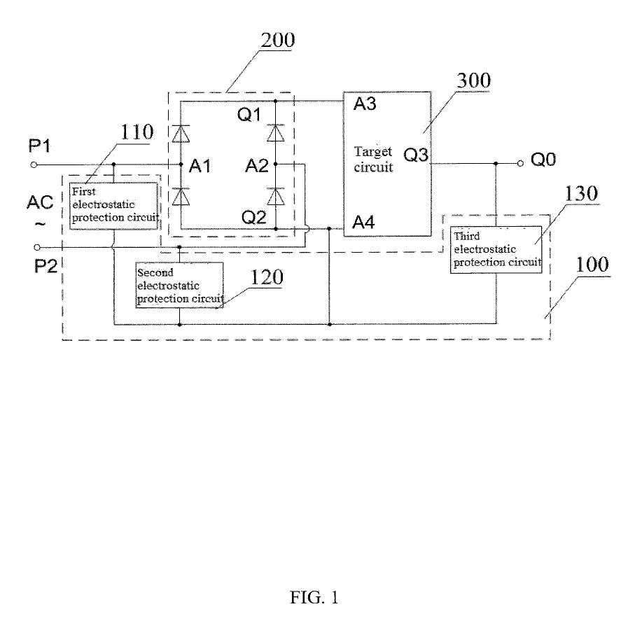

FIG. 1 shows an electronic circuit having an electrostatic function according to one embodiment. The electronic circuit can include an output port Q0, a first AC input port P1 for connecting an external AC source AC, a second AC input port P2, an electrostatic protection circuit 100, a rectifier circuit 200, and a target circuit 300. A first input terminal A1 of the rectifier circuit 200 is connected to the first AC input port P1, a second input terminal A2 of the rectifier circuit 200 is connected to the second AC input port P2. A first output terminal Q1 of the rectifier circuit 200 is connected to a first input terminal A3 of the target circuit 300 and a second output terminal Q2 of the rectifier circuit 200 is connected to a second input terminal A4 of the target circuit 300. An output terminal Q3 of the target circuit 300 is connected to the output port Q0.

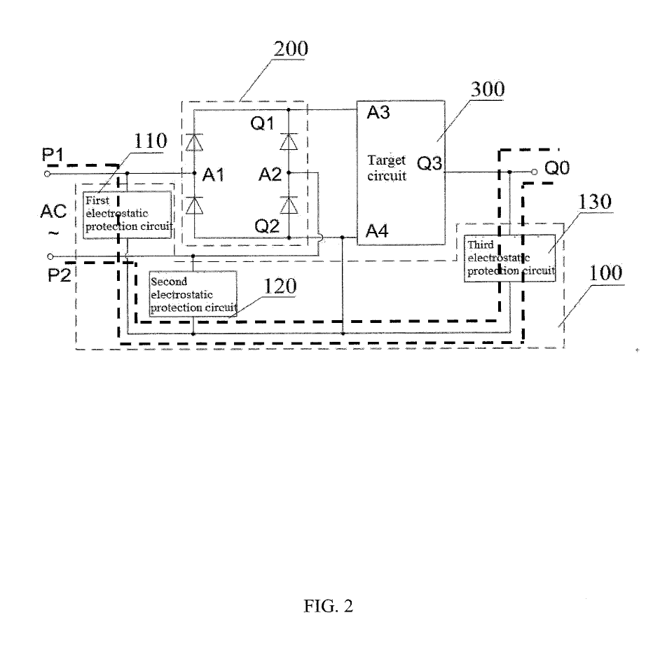

It is to be noted that, for the electronic circuit of the present application, a voltage of the first output terminal Q1 of the rectifier circuit 200 is greater than a voltage of its second output terminal Q2, and specifically, the second output terminal Q2 of the rectifier circuit 200 may be floating, as shown in FIG. 2, but is not limited thereto.

The electrostatic protection circuit 100 can include a first electrostatic protection circuit 110, a second electrostatic protection circuit 120, and a third electrostatic protection circuit 130.

One end of the first electrostatic protection circuit 110 is connected to the first AC input port P1 and the other end is connected to the second output terminal Q2 of the rectifier circuit 200. One end of the second electrostatic protection circuit 120 is connected to the second AC input port P2 and the other end is connected to the second output terminal Q2 of the rectifier circuit 200. One end of the third electrostatic protection circuit 130 is connected to the output port Q0 and the other end thereof is connected to the second output terminal Q2 of the rectifier circuit 200.

According to the configuration of the above-described electronic circuit of the present embodiment, when the external alternating current is introduced into the static electricity, the static electricity can flow through the first AC input port P1 and the second AC input port P2 of the external AC source, respectively. And then the static electricity flow through the third electrostatic protection circuit 130 and the output port Q0 to form a discharge path as a dotted line in FIG. 2. Accordingly, the static electricity introduced from the external AC source directly passes through the discharge path to avoid damaging the electronic components in the electronic circuit. A reliability of the electronic circuit can be improved.

Of course, in practical applications, if the static electricity is introduced by the output port of the electronic circuit, it can also be discharged through the discharge path formed above, so as to avoid damaging the electronic components in the target circuit. The present embodiment is not limited to the manner in which the electronic circuit is introduced. However, it should be noted that, regardless of the manner in which it is possible, the discharge path can be formed by the first electrostatic protection circuit 110, the second electrostatic protection circuit 120, and the third electrostatic protection circuit 130 or the rectifier circuit to avoid damaging the electronic components of the target circuit by static electricity. The present disclosure is not to be exhausted herein by reference to the following description of the embodiments.

The first electrostatic protection circuit 110, the second electrostatic protection circuit 120, and the third electrostatic protection circuit 130 may be a bidirectional electrostatic protection circuit, that is, the three electrostatic protection circuits can realize bidirectional conduction according to actual needs, So that the electrostatic of the electronic circuit can be discharged, and the specific circuit configuration of the three electrostatic protection circuits is not limited.

In one embodiment, the rectifier circuit 200 may include a full-wave rectifying bridge as shown in FIGS. 1 and 2, and the rectifier circuit in each embodiment of the electronic circuit described below may be exemplified by the full-wave rectifying bridge. It is to be noted that the rectifier circuit 200 is not limited to this kind of circuit structure.

In the embodiment, the discharge path can be formed by the first, second, and third electrostatic protection circuits, the static electricity introduced form the AC input port or the output port can be discharged. Thus, the static electricity does not flow through the target circuit of the electronic circuit and the electronic components can be avoided damaging.

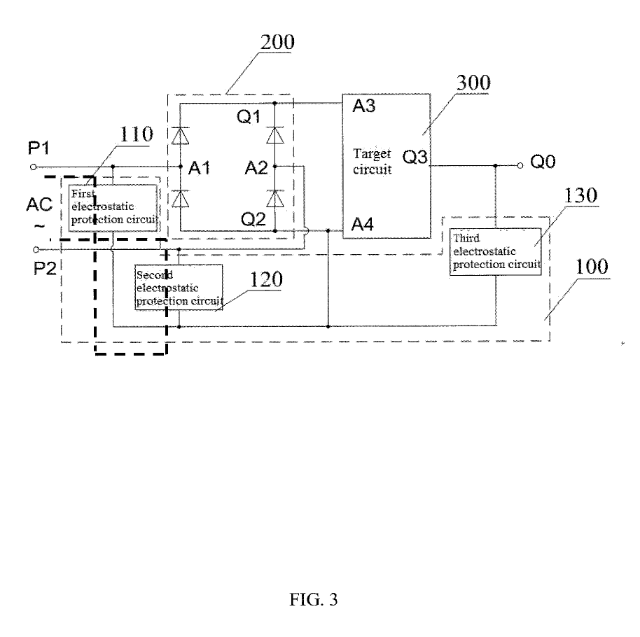

FIG. 3 shows an electronic circuit according to another embodiment. The electronic circuit of FIG. 3 is similar to the electronic circuit except some electronic components.

The electronic circuit can further include a first Zener diode ZD1 and a current limiting resistor R1 connected in series between the first output terminal Q1 and the output terminal Q2 of the rectifier circuit 200.

The first Zener diode ZD1 can be set between two terminals of the rectifier circuit 200 to stabilize the voltage. However, since the first Zener diode ZD1 is typically used for voltage clamping below several tens of volts, it can not be used to release the static voltage of the kilovolts, and the electrostatic current always passes through the first Zener diode ZD1, which can weaken its life.

The current limiting resistor R1 is coupled with the first Zener diode ZD1 with a large resistance. A voltage dividing of a branch with the first Zener diode ZD1 and the current limiting resistor R1 is increased.

As shown in FIG. 3, when the static electricity is introduced from the first AC input port P1 or the second AC input port P2 of the electronic circuit, the impedance of the branch composed of the first Zener diode ZD1 and the current limiting resistor R1 is large, the static electricity is discharged by the dotted path, so as to avoid the electrostatic current flowing through the first Zener diode ZD1 branch of the static discharge, the first Zener diode ZD1 can be protected.

The discharge path for discharging static electricity in the present embodiment is not limited to the dotted line shown in FIG. 3, and the dotted line in FIG. 2 may be formed. The specific route of formation of the discharge path is not limited to according to the specific work of the electronic circuit of the present disclosure.

The circuit configuration and the operating characteristics of the first electrostatic protection circuit 110, the second electrostatic protection circuit 120, and the third electrostatic protection circuit 130 in the present embodiment are the same as those of the corresponding electrostatic protection circuit of FIG. 1.

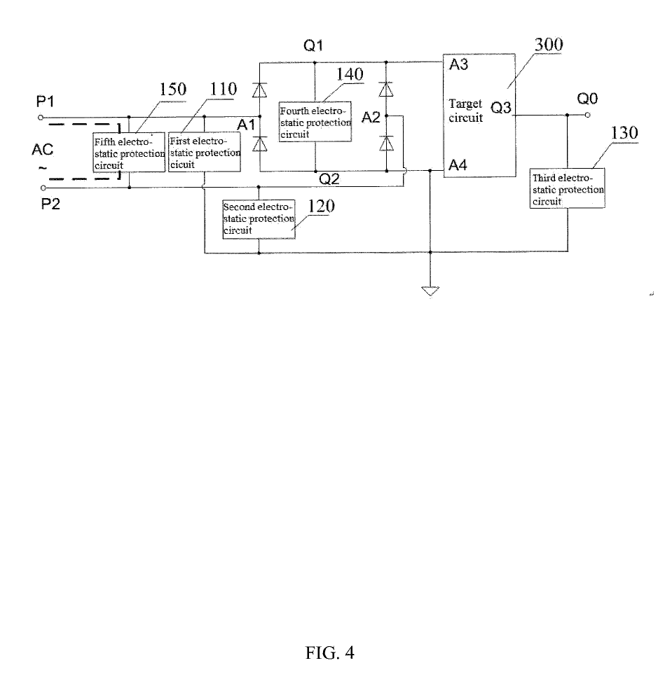

FIG. 4 shows an electronic circuit which is similar to the electronic circuit of FIG. 3 except that a number of electrostatic protection circuits.

The electrostatic protection circuit can further include a fourth electrostatic protection circuit 140 coupled between the first output port Q1 and the second output port Q2 of the rectifier circuit 200 and/or a fifth electrostatic protection circuit 150 coupled between the first AC input port P1 and the second AC input port P2.

It is to be noted that for the electrostatic protection circuit 100 including the first electrostatic protection circuit 110, the second electrostatic protection circuit 120, the third electrostatic protection circuit 130, and the fourth electrostatic protection circuit 140, but not the fifth electrostatic protection circuit 150 and the electrostatic protection circuit 100 including the first electrostatic protection circuit 110, the second electrostatic protection circuit 120, the third electrostatic protection circuit 130, and the fifth electrostatic protection circuit 150, but not the fourth electrostatic protection circuit 140 circuit structure, reference may be made to FIG. 4, which is hereby incorporated by reference.

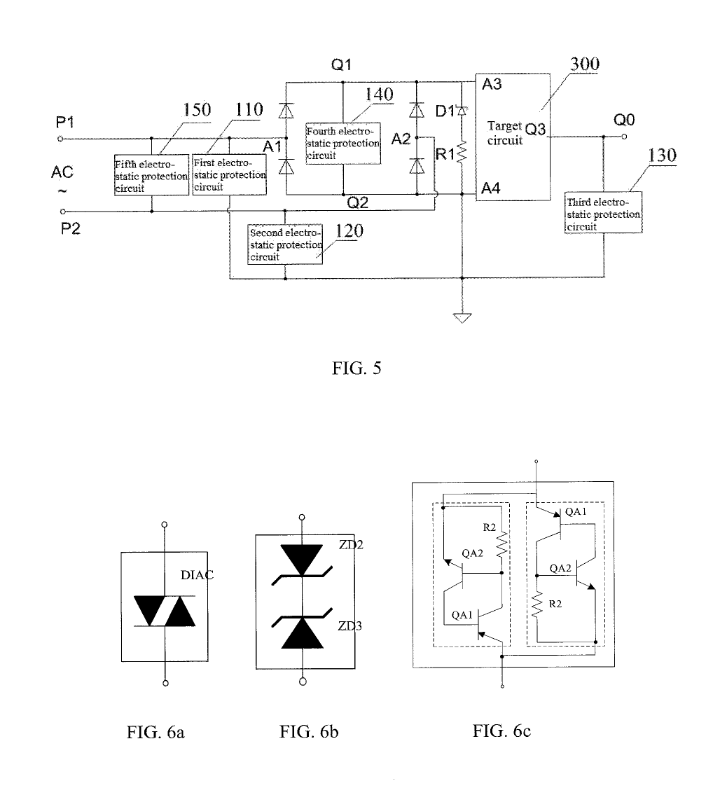

As another preferred embodiment of the present disclosure, on the basis of the above-described preferred embodiment, the electronic circuit may further include a First Zener diode ZD1 and a current limiting resistor R1 connected between the first output terminal Q1 and the second output terminal Q2 of the rectifier circuit 200, as shown in FIG. 5.

For the electronic circuit provided with the electrostatic protection circuit provided in the present embodiment, both the static electricity introduced from the input terminal and the output terminal, the output port of the electronic circuit, and the two AC input ports of the external AC power may be connected to one of the electrostatic protection circuits 100 or a plurality of electrostatic protection circuits to form a discharge path, so that the static electricity is released to avoid damaging the electronic components in the target circuit.

For the electronic circuit with the electrostatic protection circuit 100 having the fourth electrostatic protection circuit 140, when the external AC power source is supplied power to the electronic circuit, a discharge path is formed between the fourth electrostatic protection circuit 140 and the diodes in the rectifier circuit 200. A reverse breakdown of the diodes of the rectifier circuit 200 and the First Zener diode ZD1 can be avoided; thereby the internal components of the rectifier circuit and the first Zener diode ZD1 can be protected.

For the electronic circuit with the electrostatic protection circuit 100 having the fifth electrostatic protection circuit 150, the fifth electrostatic protection circuit 150 may be directly connected to the first AC input terminal P1 of the external AC power source and the second AC input terminal P2 when the external AC power is supplied to the electronic circuit. And a discharge path is formed as the dotted line in FIG. 4, so that the static electricity directly introduced by the external AC power source is released to avoid damaging the electronic components in the electronic circuit.

In the electrostatic protection circuit according to any one of the above embodiments, the specific circuit configuration of the electrostatic protection circuit will be described below by a classification method. It should be noted that the circuit configuration of the electrostatic protection circuit in the above-described embodiments is not limited to the circuit structures described below may also be constructed in other ways to form an electrostatic protection circuit, which may be modified by those skilled in the art without departing from the core elements of the present disclosure.

In the case of describing the circuit configuration of each of the electrostatic protection circuits in the electrostatic protection circuit 100 in any one of the above embodiments, the present disclosure is based only on the first electrostatic protection circuit 110 constituting the basis of the electrostatic protection circuit 100, the second electrostatic protection circuit 120 and the third electrostatic protection circuit 130 are described as an example, and circuit structures of the third electrostatic protection circuit 140 and the fifth electrostatic protection circuit 150 in the above embodiment is similar to that of the present invention are not described in details.

In one embodiment, any one of the electrostatic protection circuit 100, the first electrostatic protection circuit 110, the second electrostatic protection circuit 120, and the third electrostatic protection circuit 130 in any one of the above embodiments is provided with an electrostatic protection circuit may comprise at least one semiconductor element.

It is to be noted that the present disclosure does not limit the type, number, and composition of the at least one semiconductor element. When the electronic circuit does not generate static electricity, the at least one semiconductor element is in a high resistance state so that an operating current of electronic circuit does not pass these electrostatic protection circuits, thus avoiding the impact of these electrostatic protection circuits on the normal operation of the electronic circuit. And when the electronic circuit has an electrostatic occurrence, that is, the electronic circuit described above introduces static electricity, then the at least one semiconductor element can operate in an avalanche breakdown state so as to form a discharge path in the manner described in the above embodiments, and the static electricity can be released.

Since the discharge path does not pass through the target circuit 300, the static electricity introduced into the electronic circuit does not enter the target circuit 300, thereby preventing the electronic components in the target circuit 300 from being electrostatically destroyed.

In another embodiment, the electrostatic protection circuit can include an electrostatic detecting circuit and at least one semiconductor elements.

One of the first electrostatic protection circuit 110, the second electrostatic protection circuit 120, and the third electrostatic protection circuit 130 can include an electrostatic detecting circuit and at least one semiconductor elements.

When the electronic circuit does not generate static electricity, the at least one semiconductor element controlled by the electrostatic detecting circuit is in a high resistance state so that an operating current of electronic circuit does not pass these electrostatic protection circuits, thus avoiding the impact of these electrostatic protection circuits on the normal operation of the electronic circuit.

When the electronic circuit has an electrostatic occurrence, that is, when the electrostatic detecting circuit detects a current or voltage of the static electricity, then the at least one semiconductor element can operate in a conduction state so as to form a discharge path in the manner described in the FIGS. 2 and 3, and the static electricity can be released.

Since the discharge path formed by the electronic circuit does not pass through the target circuit, the electronic components in the target circuit are prevented from being damaged due to the sudden increase in the operating voltage with the static electricity.

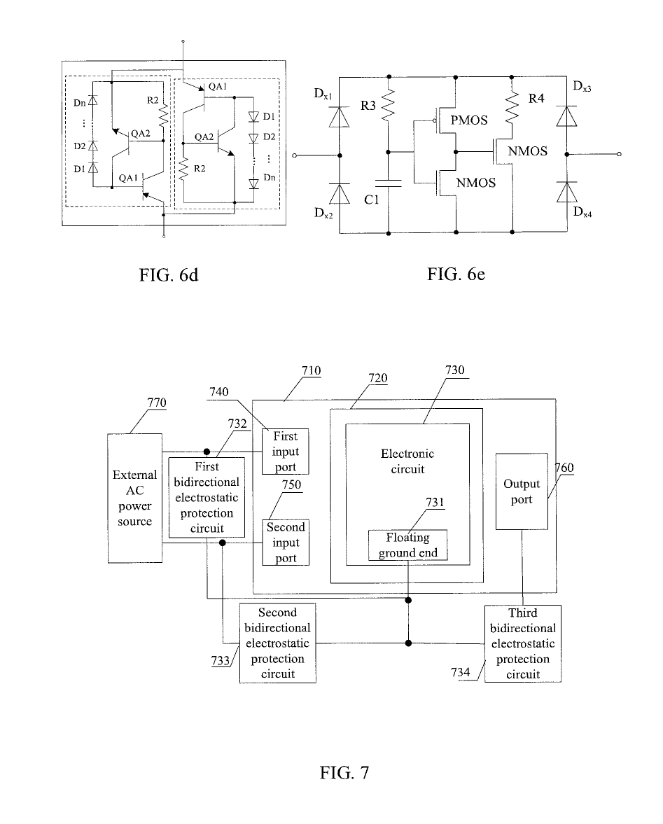

As shown in FIG. 6a, one the electrostatic circuits can include a bidirectional trigger diode, that is, any of the first electrostatic protection circuit 110, the second electrostatic protection circuit 120, and the third electrostatic protection circuit 130, and even the fourth electrostatic protection circuit 140 and the fifth electrostatic 150 may include the bidirectional trigger diode DIAC.

When the electronic circuit does not generate static electricity, the bidirectional trigger diode is in a high resistance state. And when the electronic circuit has an electrostatic occurrence, that is, the electronic circuit described above introduces static electricity, and then the bidirectional trigger diode can operate in an avalanche breakdown state so as to form a discharge path to release the static electricity.

As shown in FIG. 6b, one the electrostatic circuits can include two Zener diodes which are coupled in reverse series. Any one of the first electrostatic protection circuit 110, the second electrostatic protection circuit 120, and the third electrostatic protection circuit 130, and even the fourth electrostatic protection circuit 140 and the fifth electrostatic 150 may include a second Zener diode ZD2 and a third Zener diode ZD3. A cathode of the second Zener diode ZD2 is coupled with a cathode of the third Zener diode ZD3. An anode of the second Zener diode ZD2 and an anode of the third Zener diode ZD3 are two ports of the electrostatic protection circuit.

When the electronic circuit does not generate static electricity, the electrostatic protection circuit is not conducted. And when the electronic circuit has an electrostatic occurrence, one of the two Zener diodes is in an avalanche breakdown state and the other of the two Zener diodes is conducted, thus the electrostatic protection circuit is conducted to form the discharge path to release the static electricity.

In another embodiment, the anode of the second Zener diode ZD2 is coupled with the anode of the third Zener diode ZD3. The cathode of the second Zener diode ZD2 and the cathode of the third Zener diode ZD3 are two ports of the electrostatic protection circuit.

As shown in FIG. 6c, any one of the first electrostatic protection circuit 110, the second electrostatic protection circuit 120, and the third electrostatic protection circuit 130, and even the fourth electrostatic protection circuit 140 and the fifth electrostatic 150 may include two sub-protection circuits which are connected in reverse parallel. In the embodiment, the two sub-protection circuits can have same structures as two dashed boxes in FIG. 6c. Each of the two sub-protection circuits can include a PNP transistor QA1, an NPN transistor QA2 and a second resistor R2.

A base electrode of the PNP transistor QA1 is electrically coupled to a collector electrode of the NPN transistor QA2. A collector electrode of the PNP transistor QA1 is electrically coupled to a base electrode of the NPN transistor QA2 and electrically coupled to an emitter electrode of the NPN transistor QA2 via the second resistor R2. An emitter electrode of the PNP transistor QA2 is electrically coupled to an emitter electrode of the NPN transistor of the other sub-protection circuit. The emitter electrodes of the NPN transistor QA2 are two ports of the electrostatic protection circuit.

An operation principle of the electrostatic protection circuit having the above-mentioned structure is explained by taking the sub-protection circuit in the right-side dashed box of FIG. 6c. When the electronic circuit does not generate static electricity, the PNP transistor QA1 is turned off, the sub-protection circuit is not turned on. When the electronic circuit has static electricity (i.e. an electrostatic voltage is generated), a voltage difference between the emitter electrode and the base electrode of PNP transistor QA1 is 0.7V and a collector current is zero. Therefore, the PNP transistor QA1 is turned off so that the electrostatic voltage is mostly between the collector electrode and the emitter electrode of the NPN transistor QA2, and when the voltage between the collector electrode and the emitter electrode reaches an avalanche breakdown threshold, a leakage current can flow through the collector electrode and the emitter electrode of NPN transistor QA2, and the leakage current increases, a base current of PNP transistor QA1 will gradually increase, the PNP transistor QA1 is turned on.

Since the collector current of the PNP transistor QA1 is the base current of the NPN transistor QA2, the collector current of the PNP transistor QA1 increases as the leakage current increases when the PNP transistor QA1 is turned on, that is, the base current of NPN transistor QA2 will increase. The NPN transistor QA2 enters into a saturation state until it is fully conductive, the emitter and base electrodes of the PNP transistor QA1 and the collector and emitter electrodes of the NPN transistor QA2 has a low resistance path to form a discharge path to release the static electricity.

When the electrostatic current of the electronic circuit is entered through the port below the electrostatic protection circuit shown in FIG. 6c, the discharge path is formed by the sub-protection circuit in the left dashed box. The process is similar to the above described description of the sub-protection circuit in the right dashed box, and the present implementation will not be repeated here.

The present embodiment can use the electrostatic protection circuit of the present embodiment is bi-directionally conductive as c shown in FIG. 6c to form a discharge path to release of static electricity to avoid damaging the electronic components in the target circuit by static electricity.

FIG. 6d shows an electrostatic protection circuit which is similar to the electrostatic protection circuit of FIG. 6c except that a plurality of diodes is coupled between the collector electrode and the emitter electrode of the NPN transistor.

When the PNP transistor QA1 is turned on, the plurality of diodes are configured to clamp voltage to turn of the NPN transistor QA, thus a reverse breakdown can be avoided.

In another embodiment, the plurality of diodes can be replaced by other elements having a certain impedance to clamp voltage, and the connection manner of the other elements having a certain impedance in the electronic circuit is similar to that of the circuit shown in FIG. 6d.

As shown in FIG. 6e, any one of the first electrostatic protection circuit 110, the second electrostatic protection circuit 120, and the third electrostatic protection circuit 130, and even the fourth electrostatic protection circuit 140 and the fifth electrostatic 150 may include a first diode Dₓ₁, a second diode Dₓ₂, a third diode Dₓ₃, a fourth diode Dₓ₄, a third resistor R3, a first capacitor C1, a PMOS transistor, a first NMOS transistor, a fourth resistor R4, and a second NMOS transistor.

An anode of the first diode Dₓ₁ is electrically coupled to a cathode of the second diode Dₓ₂. A cathode of the first diode Dₓ₁ is electrically coupled to a cathode of the third diode Dₓ₃. A cathode of the fourth diode Dₓ₄ is electrically coupled to an anode of the third diode Dₓ₃. An anode of the fourth diode Dₓ₄ is electrically coupled to an anode of the second diode Dₓ₂. The cathode of the second diode Dₓ₂ and the anode of the third diode Dₓ₃ are two ports of the electrostatic protection circuit.

The first diode Dₓ₁, the second diode Dₓ₂, the third diode Dₓ₃, and the fourth diode Dₓ₄ form a full-wave rectifier bridge circuit, thus the electrostatic protection circuit is bi-directionally conductive.

One end of the third resistor R3 is electrically coupled to the cathode of the first diode Dₓ₁, the other end of the third resistor R3 is electrically coupled to one end of the first capacitor C1. The other end of the first capacitor C1 is electrically coupled to the anode of the second diode Dₓ₂.

A drain electrode of the PMOS transistor is electrically coupled to the cathode of the first diode Dₓ₁, a gate electrode of the PMOS transistor is electrically coupled to the other end of the third resistor R3 and a gate electrode of the first NMOS transistor. A source electrode of the PMOS transistor is electrically coupled to a drain electrode of the first NMOS transistor and a gate electrode of the NMOS transistor. A drain electrode of the second NMOS transistor is electrically coupled to the cathode of the first diode Dₓ₁. The source electrode of the second NMOS transistor is electrically coupled to the anode of the second diode Dₓ₂.

The specific circuit structure of each of the electrostatic protection circuits in the electrostatic protection circuit 100 can be determined according to actual needs. Specifically, it can be selected from the above-mentioned FIGS. 6a-6e.

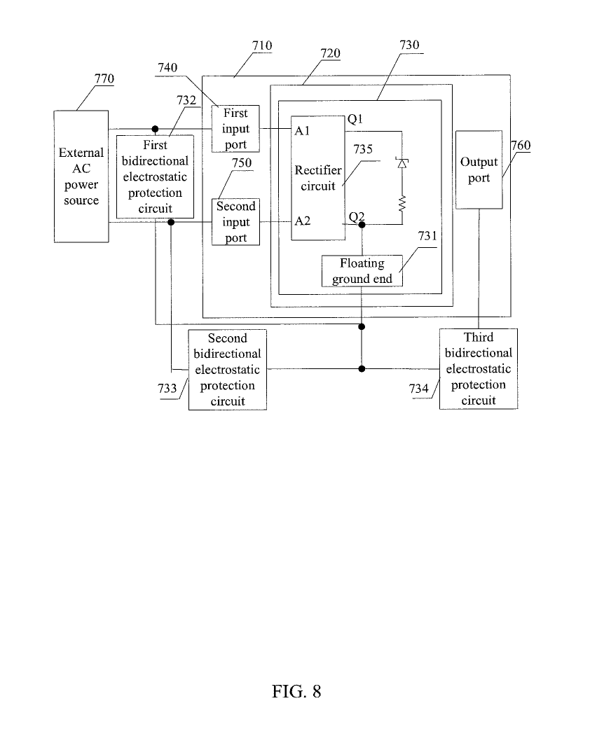

FIG. 7 shows a block diagram of an integrated circuit according to one embodiment. The integrated circuit can include a housing 710, a semiconductor substrate 720 arranged in the housing, an electronic circuit 730 arranged on the semiconductor 720. The integrated circuit can further include a first input port 740, a second input port 750, and an output port 760 which are extending from the housing 710.

The first input port 740 and the second input port 750 are coupled to an external AC power source 770.

The electronic circuit 730 can include a floating ground end 731, a first bi-directional electrostatic protection circuit 732 coupled between the first input port 740 and the floating ground end 731, a second bi-directional electrostatic protection circuit 733 coupled between the second input port 750 and the floating ground end 731, and a third bi-directional electrostatic protection circuit 734 coupled between the output port 760 and the floating ground end 731.

When static electricity is generated in the integrated circuit, a discharge path can be formed by first bi-directional electrostatic protection circuit 732, the second bi-directional electrostatic protection circuit 733, the third bi-directional electrostatic protection circuit 734, the first input port 740, the second input port 750 and the output port 760 to release static electricity. The electronic components of the electronic circuit can be avoided to damage by the static electricity.

In another embodiment, the electronic circuit 730 can further include a rectifier circuit 735 as shown in FIG. 8. The rectifier circuit 735 can include two input terminals A1 and A2, and two output terminals Q1 and Q2. The two input terminals A1 and A2 are electrically coupled to the first input port 740 and the second input port 750, respectively. One output terminal with a low voltage (Q2 as shown in FIG. 8) is electrically coupled to the floating ground end 731.

In another embodiment, the floating ground end 731 can be omitted.

As shown in FIG. 8, the electronic circuit 730 can further include a Zener diode and a current limiting resistor coupled between the two output terminals of the rectifier circuit 735 in series.

The first bi-directional electrostatic protection circuit 732, the second bi-directional electrostatic protection circuit 733, and the third bi-directional electrostatic protection circuit 734 can be selected from the first electrostatic protection circuit 110, the second electrostatic protection circuit 120, and the third electrostatic protection circuit 130, and even the fourth electrostatic protection circuit 140 and the fifth electrostatic 150 as described-above.

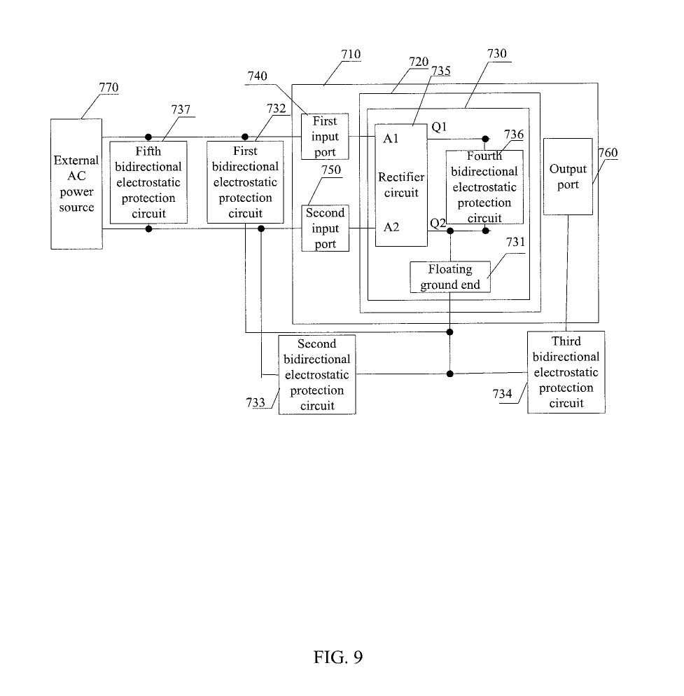

In another embodiment, as shown in FIG. 9, the electronic circuit 730 can further include a fourth bi-directional electrostatic circuit 736 coupled between two output ports of the rectifier circuit 731 and/or a fifth bi-directional electrostatic circuit 737 coupled between first input port 740 and the second input port 750.

The fourth bi-directional electrostatic circuit 736 and the fifth bi-directional electrostatic circuit 737 can have a same structure with the first, second, and third bi-directional electrostatic circuits.

Alternatively, a floating ground coupled with the floating ground end can be arranged in the housing or outside of the housing. When the floating ground arranged outside of the housing, it is also possible to provide a port outside the housing to connect with the floating ground end in the housing. Thus, when the port is a floating ground, the floating ground end in the housing is coupled to the floating ground. In another embodiment, it is also possible to directly set the floating ground end outside the housing so as to be connected to the floating ground when needed. The present disclosure is not specifically defined inside and outside the housing.

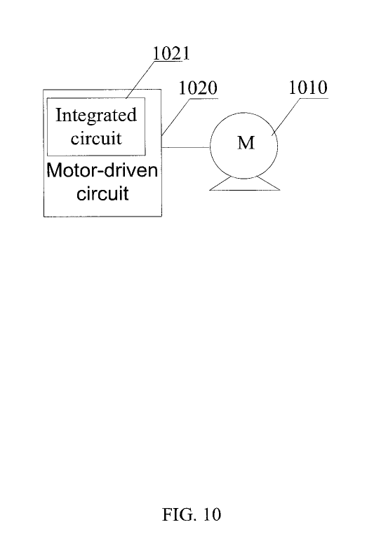

FIG. 10 shows a motor assembly according to one embodiment. The motor assembly can include a motor 1010 and a motor-driven circuit 1020. The motor-driven circuit 1020 can include an integrated circuit 1021. The integrated circuit 1021 is similar to the described-above integrated circuit, the present embodiment will not describe in detail.

Accordingly, an application apparatus is further provided according to an embodiment of the present disclosure. The application apparatus can include the motor assembly as described-above. Optionally, the application apparatus may be a pump, a fan, a household appliance, a vehicle and the like, where the household appliance, for example, may be a washing machine, a dishwasher, a range hood, an exhaust fan and the like

Described above are preferable embodiments of the present disclosure, which are not intended to limit the present disclosure. All the modifications, equivalent replacements and improvements in the scope of the spirit and principles of the present disclosure are in the protection scope of the present disclosure.

1. An electronic circuit, comprising:
an output port;
a first AC input port and a second AC input port connected with an external AC power source;
a rectifier circuit having a first input terminal coupled with the first AC input port, a second input terminal coupled with the second AC input port, a first output terminal and a second output terminal, wherein a voltage of the first output terminal is larger than a voltage of the second output terminal;
a first bidirectional electrostatic protection circuit coupled between the first AC input port and the second output terminal of the rectifier circuit;
a second bidirectional electrostatic protection circuit coupled between the second AC input port and the second output terminal of the rectifier circuit; and
a third bidirectional electrostatic protection circuit coupled between the output port and the second output terminal of the rectifier circuit.

2. The electronic circuit of claim 1, wherein the second output terminal is a floating ground end.

3. The electronic circuit of claim 1, further comprising a Zener diode and a current limiting resistor coupled between the first output terminal of the rectifier circuit and the second output terminal of the rectifier circuit in series.

4. The electronic circuit of claim 1, further comprising a fourth bidirectional electrostatic protection circuit coupled between the first output terminal and the second output terminal of the rectifier circuit.

5. The electronic circuit of claim 4, further comprising a fifth bidirectional electrostatic protection circuit coupled between the first AC input port and the second AC input port.

6. The electronic circuit of claim 5, wherein at least one of the first, second, third, fourth and fifth bidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

7. The electronic circuit of claim 5, wherein at least one of the first, second, third, fourth and fifth bidirectional electrostatic protection circuit comprises an electrostatic detection circuit and a semiconductor element, and when an static electricity is not generated in the electronic circuit, the semiconductor element is in a high resistance state; and when the static electricity is generated in the electronic circuit, the semiconductor element is controlled to be conductive by the electrostatic detection circuit to form a discharge path to release the static electricity.

8. The electronic circuit of claim 5, wherein at least one of the first, second, third, fourth and fifth bidirectional electrostatic protection circuit comprises a bidirectional trigger diode.

9. The electronic circuit of claim 5, wherein at least one of the first, second, third, fourth and fifth bidirectional electrostatic protection circuit comprises a first Zener diode and a second Zener diode; a cathode of the first Zener diode is coupled with a cathode of the second Zener diode, an anode of the first Zener diode and an anode of the second Zener diode are two ports of the bidirectional electrostatic protection circuit.

10. The electronic circuit of claim 5, wherein at least one of the first, second, third, fourth and fifth bidirectional electrostatic protection circuit comprises a first Zener diode and a second Zener diode; an anode of the first Zener diode is coupled with an anode of the second Zener diode, a cathode of the first Zener diode and a cathode of the second Zener diode are two ports of the bidirectional electrostatic protection circuit.

11. The electronic circuit of claim 5, wherein at least one of the first, second, third, fourth and fifth bidirectional electrostatic protection circuit comprises two sub-protection circuits which are connected in reverse parallel, each of the two sub-protection circuits comprises a PNP transistor, an NPN transistor, a second resistor and a plurality of diodes;
a base electrode of the PNP transistor is electrically coupled with a collector electrode of the NPN transistor;
a collector electrode of the PNP transistor is electrically coupled with a base electrode of the NPN transistor and coupled to an emitter electrode of the NPN transistor via the second resistor;
the plurality of diodes are coupled between the collector electrode NPN transistor and the emitter electrode of the NPN transistor; and
an emitter electrode of the PNP transistor is electrically coupled to the emitter electrode of the NPN transistor of the other sub-protection circuit, the emitter electrodes of the NPN transistor in two sub-protection circuits are two ports of the bidirectional electrostatic protection circuit.

12. The electronic circuit of claim 5, wherein at least one of the first, second, third, fourth and fifth bidirectional electrostatic protection circuit comprises a first diode, a second diode, a third diode, a fourth diode, a third resistor, a first capacitor, a PMOS transistor, a first NMOS transistor, a fourth resistor, and a second NMOS transistor;
an anode of the first diode is electrically coupled with a cathode of the second diode, a cathode of the first diode is electrically coupled with a cathode of the third diode, a cathode of the second diode and an anode of the third diode are two ports of the bidirectional electrostatic protection circuit;
a cathode of the fourth diode is electrically coupled with an anode of the third diode, an anode of the fourth diode is electrically coupled with an anode of the second diode;
one end of the third resistor is electrically coupled with the cathode of the first diode, the other end of the third resistor is electrically coupled with one end of the first capacitor, the other end of the first capacitor is electrically coupled with the anode of the second diode;
a drain of the PMOS is electrically coupled with the cathode of the first diode, a gate of the PMOS is electrically coupled with the other end of the third resistor and a gate of the first NMOS transistor, a source of the PMOS is electrically coupled with a drain of the first NMOS transistor and a gate of the second NMOS, a source of the first NMOS is electrically coupled with the anode of the second diode; and
a drain of the second NMOS transistor is electrically coupled with the cathode of the first diode via the fourth resistor, a source of the NMOS transistor is electrically coupled with the anode of the second diode.

13. An integrated circuit, comprising:
a housing;
a semiconductor substrate arranged in the housing;
an electronic circuit arranged on the semiconductor;
a first input port, a second input port, and an output port which extending from the housing;
wherein the electronic circuit comprises a floating ground end;
a first bidirectional electrostatic protection circuit coupled between the first input port and the floating ground end;
a second bidirectional electrostatic protection circuit coupled between the second input port and the floating ground end; and
a third bidirectional electrostatic protection circuit coupled between the output port and the floating ground end.

14. The integrated circuit of claim 13, wherein the electronic circuit further comprises a rectifier circuit having a first input terminal coupled to the first input port, a second input terminal coupled to a second input port, a first output terminal and a second output terminal.

15. The integrated circuit of claim 14, wherein the electronic circuit further comprises a fourth bidirectional electrostatic protection circuit coupled between the first output terminal and the second output terminal of the rectifier circuit.

16. The integrated circuit of claim 15, wherein the electronic circuit further comprises a fifth bidirectional electrostatic protection circuit coupled between the first input port and the second input port.

17. The integrated circuit of claim 15, wherein at least one of the first, second, third, fourth and fifth bidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

18. The integrated circuit of claim 15, wherein at least one of the first, second, third, fourth and fifth bidirectional electrostatic protection circuit comprises an electrostatic detection circuit and a semiconductor element, and when an static electricity is not generated in the electronic circuit, the semiconductor element is in a high resistance state; and when the static electricity is generated in the electronic circuit, the semiconductor element is controlled to be conductive by the electrostatic detection circuit to form a discharge path to release the static electricity.

19. A motor assembly, comprising:
a motor and a motor-driven circuit, wherein the motor-driven circuit comprises the integrated circuit of claim 13.
